(19) United States
(12) Patent Application Publication
(10) Pub. No.: US 2008/0173791 A1
(43) Pub. Date: Jul. 24, 2008

(54) IMAGE SENSOR WITH THREE SETS OF MICROLENSES

(76) Inventor: Russell J. Palum, Rochester, NY (US)

Correspondence Address: Frank Pincelli;Patent Legal Staff, Eastman Kodak Company, 343 State Street, Rochester, NY, 14650-2201, US

(21) Appl. No.: 11/624,791

(22) Filed: Jan. 19, 2007

(51) Int. Cl. H01L 27/14

(52) U.S. Cl. 250/208.1

(57) ABSTRACT

An image sensor includes a substrate having a plurality of photosensitive sites; a plurality of first microlenses spanning the pixels and respectively aligned with the plurality of photosensitive sites that receives incident light; an optically transmissive layer positioned between the substrate and the plurality of first microlenses; a layer of second microlenses positioned between the first microlenses and the optically transmissive layer that receives the incident light from the plurality of first microlenses for focusing the incident light onto a plane between the photosensitive sites and the first layer of microlenses; and a layer of third microlenses positioned between the optically transmissive layer and the photosensitive sites that receives the incident light from the first layer of microlenses for focusing the incident light onto the photosensitive sites.

### FIELD OF THE INVENTION

The invention relates generally to the field of image sensors and, more particularly, to such image sensors having microlenses with an effective short focal length lens with a long overall length.

### BACKGROUND OF THE INVENTION

The pixel structure of an electronic imager influences the efficiency of photon to electron conversion for the imager. The market is driving the imager industry to compact cameras that use small electronic imagers with millions of pixels. This leads to very small pixel pitches.

Some features of an electronic imager do not scale well with pixel pitch. The ratio of photosensitive area (active area) to pixel area is reduced because the overhead of the reset and readout structure does not scale with the pixel size. The depth that each layer in an electronic imager requires is also not reduced in proportion to pixel pitch. This leads to a relatively large space between the surface of the imager and the active area. CMOS imagers have more dielectric and metal layers above the active area than CCD imagers so the space above the active area is more of a problem for CMOS imagers than CCD imagers.

Electronic imagers use microlens arrays to increase the effective photoactive area. Ideally, each lenslet in a microlens array collects all of the light that falls on its surface and directs the light to the active area. The lenslet can only direct rays entering the imager with an angle below a certain angle onto the active photosensitive area. Rays beyond this angle are lost. The size of the active area and the focal length of the lenslet determine this angle. The angle limits maximum lens aperture size and it limits the choice of lens. Some types of lenses produce very steep ray angles near the edge of the image and can't be used with imagers that are sensitive to ray angle.

Consequently, a need exists for an image sensor, particularly image sensors with very small pixel pitches, to have an optical system that more efficiently focuses light into the photosensitive regions.

### SUMMARY OF THE INVENTION

The present invention is directed to overcoming one or more of the problems set forth above. Briefly summarized, according to one aspect of the present invention, the invention resides in an image sensor comprising (a) a substrate having a plurality of photosensitive sites; (b) a plurality of first microlenses spanning the pixels and respectively aligned with the plurality of photosensitive sites that receives incident light; (c) an optically transmissive layer positioned between the substrate and the plurality of first microlenses; (d) a layer of second microlenses positioned between the first microlenses and the optically transmissive layer that receives the incident light from the plurality of first microlenses for focusing the incident light onto a plane between the photosensitive sites and the first layer of microlenses; and (e) a layer of third microlenses positioned between the optically transmissive layer and the photosensitive sites that receives the light from the second layer of microlenses for focusing the incident light onto the photosensitive sites.

The above and other objects of the present invention will become more apparent when taken in conjunction with the following description and drawings wherein identical reference numerals have been used, where possible, to designate identical elements that are common to the figures.

### ADVANTAGEOUS EFFECT OF THE INVENTION

The present invention has the advantage of an optical system with an effective short focal length lens with a long overall length.

### BRIEF DESCRIPTION OF THE DRAWINGS

FIG. 1 is a top view of the image sensor of the present invention;

FIG. 2 is a side view of an image sensor and its associated optical system of the present invention;

FIG. 3 is a digital camera having the image sensor and optical system of the present invention; and

FIG. 4 is a side view of lenses that are preferably used, but not limited to, in the present invention.

### DETAILED DESCRIPTION OF THE INVENTION

Before discussing the present invention in detail, it is instructive to note that the present invention is preferably used in, but not limited to, either an active image sensor or a CMOS active pixel sensor. Active pixel sensor refers to an active electrical element within the pixel, other than transistors functioning as switches. For example, the floating diffusion or amplifier are active elements. CMOS refers to complementary metal oxide silicon type electrical components such as transistors which are associated with the pixel, but typically not in the pixel, and which are formed when the source/drain of a transistor is of one dopant type and its mated transistor is of the opposite dopant type. CMOS devices include some advantages one of which is it consumes less power.

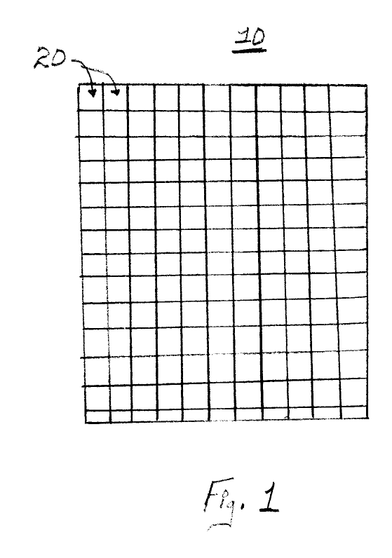

Referring to FIG. 1, there is shown an image sensor 10 having a plurality of pixels 20 each having a photosensitive site (not shown in FIG. 1). As stated above, the image sensor 10 is preferably an active image sensor or a CMOS active image sensor, although a charge-coupled device may also be used.

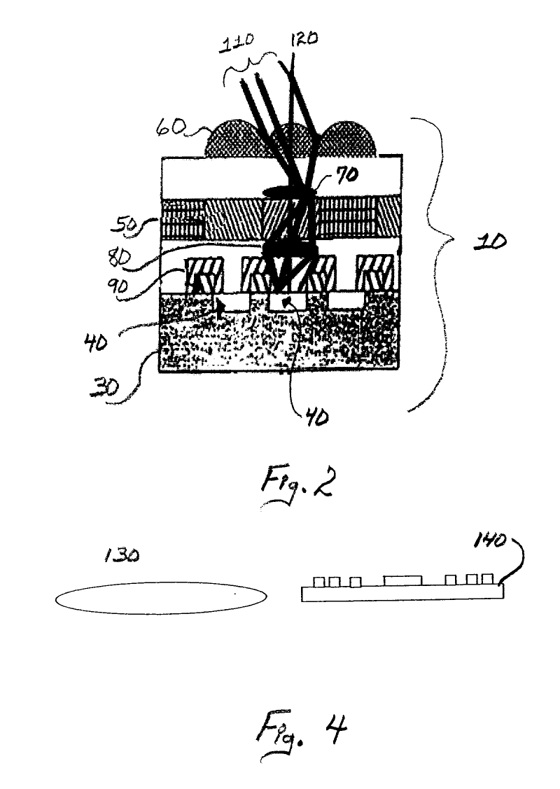

Referring to FIG. 2, there is shown a portion of the image sensor 10 having its associated optical system of the present invention. The image sensor 10 includes a substrate 30 having a plurality of photosensitive sites 40 arranged in an array for collecting charge in response to incident light. A color filter array 50 is disposed spanning and covering (in a spaced-apart relationship) the photosensitive sites 40 for permitting specific bandlengths of light to pass there through. Preferably, a Bayer color filter is used, although other filters may also be used. A plurality or first set of microlenses 60 are disposed spanning and covering (in a spaced-apart relationship) the color filter array 50. The first set of microlenses 60 are positioned in predetermined alignment with the color filter array 50 and the photosensitive sites 40 so that initial incident light that passes there through is directed toward its mated photosensitive site 40. It is noted that as defined herein the initial incident light is the light incident on the first set of microlenses.

Another plurality or second set of microlenses 70 (only one is shown for simplicity of understanding) is disposed between the first set of microlenses 60 and the photosensitive sites 40 or active area for directing the incident light received from the first set of microlenses 60 toward the photosensitive sites 40. As may be apparent, the second set of microlenses 70 are also aligned in a predetermined relationship with the color filter array 50 and photosensitive sites 40 so that incident passing through the second set of microlenses 70 is directed toward its mated photosensitive site 40. The second set of microlenses 70 is preferably positioned between the first set of microlenses 60 and the color filter array 50. Alternatively, the second set of microlenses 70 could be below or interdisposed with the color filter array 50. Still further, the color filter array 50 could function both as the color filter array and the second layer of microlenses. A plurality or third set of microlenses 80 (only one is shown for simplicity of understanding) is disposed between the second set of microlenses 70 and the photosensitive sites 40 and receives the incident light from the second set of microlenses 70 and directs it toward the photosensitive sites 40. The third set of microlenses 80 is held in position by the color filter array 50 and/or any of the intervening dielectric layers or metal layers such as lightshields 90, as is well known in the art. As may be apparent, the third set of microlenses 80 are also aligned in a predetermined relationship with the color filter array 50 and photosensitive sites 40 so that incident passing through the second set of microlenses 70 is directed toward its mated photosensitive site 40.

As is apparent from the above description, the first 60, second 70 and third 80 microlenses are optically transmissive. Still further, the second 70 and third 80 microlenses preferably have an index of refraction different to any surrounding material such that light is bent at an interface of both the second 70 and third 80 microlenses.

These three lenses (60, 70 and 80) can be cooptimized using optical lens design techniques, but using first order (paraxial) optics, the first lens 60 acts like a standard microlens with a short focal length. The second lens 70 acts like a field lens and bends the off-axis cone 110 of rays so it passes through the third (relay) lens 80 and relays the image formed by the first set of microlenses 60 to the active area 40. It should be noted that the on-axis cone of rays 120 is not bent and does not need to be bent, but nevertheless they are directed toward the photosensitive sites 40.

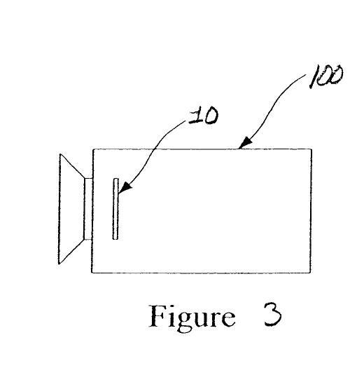

Referring to FIG. 3, there is shown a digital imaging system 100, preferably a digital camera, having the image sensor 10 of the present invention disposed therein. The digital imaging system 100 captures either still or video images via the image sensor and optical system of the present invention.

Referring to FIG. 4, the microlenses 60, 70 and 80 are preferably refractive lenses 130 but may be diffractive lenses 140. These are easier to produce using standard semi-conductor fabrication techniques.

The invention has been described with reference to a preferred embodiment. However, it will be appreciated that variations and modifications can be effected by a person of ordinary skill in the art without departing from the scope of the invention.

### PARTS LIST

10 image sensor
20 pixels
30 substrate
40 photosensitive sites
50 color filter array
60 first set of microlenses
70 second set of microlenses
80 third set of microlenses
90 lightshield
100 digital imaging system
110 off-axis cone of rays
120 on-axis cone of rays
130 refractive lenses
140 diffractive lenses

1. An image sensor comprising:
(a) a substrate having a plurality of photosensitive sites;
(b) a set of first microlenses spanning the pixels and respectively aligned with the plurality of photosensitive sites that receives initial incident light;
(c) a set of second microlenses that receives the incident light from the plurality of first set of microlenses on one side and focuses the received incident light onto a predetermined plane on an opposite side; wherein an on-axis and off-axis cone of rays are directed to the predetermined plane; and
(d) a set of third microlenses that receives the incident light from the second set of microlenses for focusing the initially incident light onto the photosensitive sites.

2. The image sensor as in claim 1 further comprising an optical transmissive layer.

3. The image sensor as in claim 2, wherein the optical transmissive layer is a color filter array.

4. The image sensor as in claim 1, wherein the first and second layer of microlenses are respectively aligned with respect to the photosensitive sites.

5. The image sensor as in claim 1, wherein the second microlenses have an index of refraction and the third microlenses have an index of refraction in which both index of refractions have an index of refraction relative to any surrounding material such that light is bent at an interface of both the second and third microlenses.

6. The image sensor as in claim 1, wherein any combination of the first, second and third set of microlenses are constructed as a diffractive lens.

7. A camera comprising:
an image sensor comprising:
(a) a substrate having a plurality of photosensitive sites;
(b) a set of first microlenses spanning the pixels and respectively aligned with the plurality of photosensitive sites that receives initial incident light;
(c) a set of second microlenses that receives the incident light from the plurality of first set of microlenses on one side and focuses the received incident light onto a predetermined plane on an opposite side; wherein an on-axis and off-axis cone of rays are directed to the predetermined plane; and
(d) a set of third microlenses that receives the incident light from the second set of microlenses for focusing the initially incident light onto the photosensitive sites.

8. The camera as in claim 7 further comprising an optical transmissive layer.

9. The camera as in claim 8, wherein the optical transmissive layer is a color filter array.

10. The camera as in claim 7, wherein the first and second set of microlenses are respectively aligned with respect to the photosensitive sites.

11. The camera as in claim 7, wherein the second set of microlenses have an index of refraction and the third set of microlenses have an index of refraction in which both index of refractions have an index of refraction relative to any surrounding material such that light is bent at an interface of both the second and third microlenses.

12. The camera as in claim 7, wherein any combination of the first, second and third set of microlenses are constructed as a diffractive lens.
